(19) United States
(12) Patent Application Publication
(10) Pub. No.: US 2021/0385984 A1
(43) Pub. Date: Dec. 9, 2021

(54) MULTIFUNCTIONAL FLEXIBLE LAMINATES, RELATED ARTICLES, AND METHODS

(71) Applicant: DUPONT ELECTRONICS, INC., Wilmington, DE (US)

(72) Inventors: NADIA MARIE KROOK, PHILADELPHIA, PA (US); JEFFREY SCOTT METH, LANDENBERG, PA (US); INGRID FULLER GUHA, GLEN MILLS, PA (US); SUSAN MARIE HERCZEG, CARMEL, IN (US)

(21) Appl. No.: 17/330,007

(22) Filed: May 25, 2021

Related U.S. Application Data
(60) Provisional application No. 63/036,943, filed on Jun. 9, 2020.

(51) Int. Cl. H05K 9/00; B32B 9/00; B32B 9/04; B32B 7/12; B32B 3/26; B32B 15/04

(52) U.S. Cl. CPC H05K 9/0088; B32B 9/007; B32B 9/041; B32B 7/12; B32B 2307/546; B32B 15/043; B32B 2307/732; B32B 2307/302; B32B 2307/212; B32B 3/266

(57) ABSTRACT

The present disclosure is directed to a multifunctional flexible laminate, an electronic device comprising the multifunctional flexible laminate, and methods for making and using the multifunctional flexible laminate in the electronic device.

This application claims the benefit of provisional patent application No. 63/036,943, filed Jun. 9, 2020, which is hereby incorporated by reference herein in its entirety.

### FIELD

The present disclosure is directed to a multifunctional flexible laminate, an electronic device comprising the multifunctional flexible laminate, and methods for making and using the multifunctional flexible laminate in the electronic device.

### BACKGROUND

Electromagnetic interference (EMI), also called radio-frequency interference (RFI) in the radio frequency spectrum, is a disturbance generated by an external source that adversely affects electrical circuits by electromagnetic induction, electrostatic coupling, or conduction. This disturbance may degrade the performance of chip packages or even stop them from functioning. In the case of data transmission, the impact of these effects can range from an increase in error rate to a total loss of data. Electrostatic discharge occurs when static electricity is accumulated because of friction between dissimilar material surfaces rubbing together, even only briefly. Electrostatic discharge has the potential to damage sensitive electronic components, change magnetic media, and ignite flammable environments. Due to widespread implementation and use of electronic products and their continuous performance improvement as a result of technological advancements, electromagnetic energy in the electronic products may increase, and therefore the reduction of electromagnetic interference becomes critical.

As technology continues to evolve, electronic systems are becoming more efficient while the design requirements are trending to smaller and thinner devices. Furthermore, power density is increasing as components shrink in size. During periods of high data transmission or data processing, advanced electronic components and chip packages will inevitably generate increasingly more heat. High-temperature working environments will not only degrade the efficiency of electronic systems, but the excessive temperatures are also more likely to cause permanent hardware damage or failure in a variety of applications. Thermal management solutions are required to effectively dissipate heat within electronic devices to maintain reasonable working temperatures and provide an even heat distribution to avoid hotspots. Generally, high thermal conductivity materials are used as heat transfer agents to dissipate heat from the electronic system. Among high thermal conductivity materials, graphitic materials are desired because of their ability to conduct heat. Despite its high in-plane thermal conductivity and heat spreading potential, graphitic material is brittle and poses flaking risks that could damage circuits. Therefore, advanced thermal management composites containing a graphitic core for high thermal diffusivity need to be flexible while also eliminating the risk for exposed edges or flakes.

The market shifts to flexible electronic devices such as flexible displays, smartphones, and wearable technologies coupled with increasing power density, smaller chip packages, and the presence of electrostatic fields highlight the need for flexible multifunctional material systems capable of effectively dissipating heat while also shielding electromagnetic interference.

### DETAILED DESCRIPTION

As used throughout this specification, the following abbreviations shall have the following meanings, unless the context clearly indicates otherwise: ° C.=degree Celsius; K=degree Kelvin; W=Watts; g=gram; nm=nanometer; μm=micron=micrometer; mm=millimeter; s=second; and min=minute. All amounts are percent by weight (wt %) and all ratios are molar ratios, unless otherwise noted. All numerical ranges are inclusive and combinable in any order, except where it is clear that such numerical ranges are constrained to added up to 100%. Unless otherwise noted, all polymer and oligomer molecular weights are weight average molecular weights (M_{w}) with unit of g/mol or Dalton and are determined using gel permeation chromatography compared to polystyrene standards.

The articles “a”, “an” and “the” refer to the singular and the plural, unless the context clearly indicates otherwise. As used herein, the term “and/or” includes any and all combinations of one or more of the associated items. The term “polymer” refers to molecules composed of repeating monomer units. The term “copolymer” refers to a polymer composed of two or more chemically dissimilar monomers as polymerized units, and includes block copolymers, terpolymers, tetra polymers, and the like. Polymers and copolymers in the present disclosure may contain organic and/or inorganic additives.

It will be understood that although the terms first, second, third, etc. may be used herein to describe various elements, components, regions, layers and/or sections, these elements, components, regions, layers, and/or sections should not be limited by these terms. These terms are only used to distinguish one element, component, region, layer and/or section from another element, component, region, layer and/or section. Thus, a first element, component, region, layer and/or section could be termed a second element, component, region, layer and/or section without departing from the teachings of the present disclosure. Similarly, the terms “top” and “bottom” are only relative to each other. It will be appreciated that when an element, component, layer or the like is inverted, what is the “bottom” before being inverted would be the “top” after being inverted, and vice versa. When an element is referred to as being “on” or “disposed on” another element, it means positioning on or below the object portion, but does not essentially mean positioning on the upper side of the object portion based on a gravity direction, and it can be directly on the other element or intervening elements may be present therebetween. In contrast, when an element is referred to as being “directly on” or “disposed directly on” another element, there are no intervening elements present.

Furthermore, it will also be understood that when one element, component, region, layer and/or section is referred to as being “between” two elements, components, regions, layers and/or sections, it can be the only element, component, region, layer and/or section between the two elements, components, regions, layers and/or sections, or one or more intervening elements, components, regions, layers and/or sections may also be present.

The term “metal foil” refers to a piece of metal whose thickness is significantly smaller than its longitudinal and transverse dimensions. The metal foil according to the present disclosure is made of one integral piece of metal. The metal foil can, for instance, be produced by electrodeposition, or deep drawing or rolling of one piece of metal. For example, for electrodeposition high grade metal such as copper has to be dissolved in an acid to produce a copper electrolyte. This electrolyte solution is pumped into partially immersed, rotating drums which are electrically charged. On these drums a thin film of copper is electrodeposited. This process is also known as plating. Coils of thin foils are formed and undergo subsequent chemical and mechanical treatment until they are formed into their final shape.

The term “via” refers to a hole or aperture that extends through a substrate. The terms “via” and “hole” are used interchangeably through this specification.

The terms “film” refers to a sheet-like material wherein the length and width of the material far exceed the thickness of the material. The “film” includes “layer” and “sheet” like structure. The terms “film”, “layer” and “sheet” are used interchangeably through this specification. A layer can be one layer or plurality of layers having the different physical properties or the same physical properties but different polymeric compositions.

The present disclosure relates to a multifunctional flexible laminate comprising a substrate, at least one graphite sheet, and at least one adhesive layer. The present disclosure also relates to a multifunctional flexible laminate comprising a plurality of layers having at least one graphite sheets and at least one adhesive layers.

In a first aspect, a multifunctional flexible laminate comprises a substrate, a first graphite sheet disposed on the substrate, and a first adhesive layer disposed on the first graphite sheet. The multifunctional flexible laminate can further comprise a second graphite sheet disposed on the first adhesive layer, and a second adhesive layer disposed on the second graphite sheet. In addition, the multifunctional flexible laminate can further comprise a third graphite sheet disposed on the second adhesive layer, and a third adhesive layer disposed on the third graphite sheet. More graphite sheets and the adhesive layers can be added according to this order in the multifunctional flexible laminate described above. For example, the multifunctional flexible laminate can further comprise a fourth graphite sheet disposed on the third adhesive layer and a fourth adhesive layer, or can further comprise a fifth graphite sheet disposed on the fourth adhesive layer and a fifth adhesive layer, or more layers of the graphite sheets and adhesive layers to be added based on the order.

In a second aspect, a multifunctional flexible laminate comprises a substrate, a first adhesive layer disposed on the substrate, a first graphite sheet disposed on the first adhesive layer, a second adhesive layer disposed on the first graphite sheet, a second graphite sheet disposed on the second adhesive layer, and a third adhesive layer disposed on the second graphite sheet. The multifunctional flexible laminate can further comprise a third graphite sheet disposed on the third adhesive layer, and a fourth adhesive layer disposed on the third graphite sheet.

In a third aspect, a multifunctional flexible laminate comprises a first adhesive layer, a first graphite sheet disposed on the first adhesive layer, a second adhesive layer disposed on the first graphite sheet, a second graphite sheet disposed on the second adhesive layer, and a third adhesive layer disposed on the second graphite sheet. The multifunctional flexible laminate can further comprise a third graphite sheet disposed on the third adhesive layer, and a fourth adhesive layer disposed on the third graphite sheet. More graphite sheets and the adhesive layers can be added according to this order in the multifunctional flexible laminate described above.

In a fourth aspect, a multifunctional flexible laminate comprising a first graphite sheet, a first adhesive layer disposed on the first graphite sheet, a substrate disposed on the first adhesive layer, a second adhesive layer disposed on the substrate, and the second graphite sheet disposed on the second adhesive layer.

In some embodiments, the graphite sheets described above can comprise a plurality of vias, slits, louvers, or their combinations thereof.

In a fifth aspect, a multifunctional flexible laminate comprising a first and second adhesive layers, and a graphite sheet having a plurality of vias, slits, louvers, or their combinations thereof sandwiched between the first and second adhesive layers.

A multifunctional flexible laminate of the present disclosure can comprise any combinations of the multifunctional flexible laminates described above, and their combinations can be made based on unique designs to meet the specific requirements of electronic devices.

The graphite sheet in the present disclosure is not particularly restricted as long as the graphite sheet is a sheet composed of graphite. Examples of the graphite sheets suitable for the present disclosure can include, but are not limited to, an artificial graphite sheet (AGS), a natural graphite sheet (NGS), an artificial/natural graphite composite sheet (AGS/NGS), or their combinations thereof.

The artificial graphite sheet can be made from a synthetic resin sheet. In some embodiments, the artificial graphite sheet can be made from graphitizing an aromatic polyimide film. The aromatic polyimide film can be made from polymerizing diamines and dianhydrides to form a polyamic acid. The polyamic acid is solvent casted on a substrate and hot baked to form a polyamic acid film or gel film which may be freestanding and not attached to the substrate. The polyamic acid film or gel film is biaxially stretched at a high temperature imidization or chemical imidization to form the polyimide film. The polyimide film is then carbonized and graphitized to form a graphite sheet. The polyimide film can include, but is not limited to, Kapton® GS polyimide film (DuPont Specialty Products USA, LLC, Wilmington, Del.). The dianhydride can be selected from the group consisting of pyromellitic dianhydride (PMDA), 3,3′,4,4′-biphenyltetracarboxylic dianhydride (BPDA), 4,4′-(hexafluoroisopropylidene)diphthalic anhydride (6FDA), cyclobutane-1,2,3,4-tetracarboxylic dianhydride (CBDA), 3,3′,4,4′-benzophenonetetracarboxylic dianhydride, 3,3′,4,4′-diphenylsulfonetetracarboxylic dianhydride, an alicyclic dianhydride and combinations thereof. The diamine can be an aromatic diamine such as p-phenylene diamine, m-phenylene diamine, 4,4′-oxydianiline, or combinations thereof. The diamine can be a fluorinated aromatic diamine such as 2,2′-bis(trifluoromethyl)-4,4′-diamino biphenyl (TFMB). The diamine can also be an aliphatic amine selected from the group consisting of 1,2-diamninoethane, 1,6-diaminohexane, 1,4-diaminobutane, 1,5-diaminopentane, 1,7-diaminoheptane, 1,8-diaminooctane, 1,9-diaminononane, 1,10-diaminodecane, 1,11-diaminoundecane, 1,12-diaminododecane, 1,16-hexadecamethylenediamine, 1,3-bis(3-aminopropyl)-tetramethyldisiloxane, isophoronediamine, bicyclo[2.2.2]octane-1,4-diamine and combinations thereof. The artificial graphite sheet and preparation are disclosed in U.S. Patent Nos. 6,027,807 and 9,593,207, the entire contents of which are incorporated herein by reference. Commercial artificial graphite sheet can include, but are not limited to, eGRAF® SPREADERSHIELD™ synthetic graphite products (NeoGraf Solutions, LLC Lakewood, Ohio) and T68 (T-Global Technology Co., Ltd, Taoyuan City, Taiwan).

In some embodiments, the artificial graphite sheet can be a pyrolytic graphite sheet. The pyrolytic graphite sheet is a thermal interface material which is very thin, synthetically made, has high thermal conductivity, and is made from a highly oriented graphite polymer film. In some embodiments, a pyrolytic graphite refers to the carbon material produced through a gas-phase carbonization process. The gas-phase deposition of carbon occurs on a surface through the contact of hydrocarbons upon a substrate by the pyrolysis of hydrocarbons in the gas phase and deposition on the substrate surface. The large aromatic molecules produced by dehydrogenation and polymerization of hydrocarbons collide with the high-temperature substrate surface to form the deposit. Hydrogen is often used as a carrier gas with propane as a potential raw material with the concentration of propane depending upon the selected temperature and pressure conditions. The specific conditions of the reaction are selected for the prevention of soot and production of depositions, typically keeping the hydrocarbon gas at the lowest possible temperature where carbonization is completed when the gas contacts the substrate surface.

The natural graphite sheet is a porous, anisotropic, and compressible material, which is also known as flexible graphite, graphite foil, or compressed exfoliated natural graphite. It can be manufactured from graphite particles, wherein at least some of the particles are intercalated, exfoliated, expanded natural graphite. In some embodiments, the natural graphite sheet can be made by compressing exfoliated natural graphite flake particles (worms) without using a binder. Commercial natural graphite sheets can include, but are not limited to, eGRAF® SPREADERSHIELD™ natural graphite products (NeoGraf Solutions, LLC Lakewood, Ohio).

The composite sheet of artificial and natural graphite comprises at least one natural graphite layer and at least one artificial graphite layer, where each natural graphite layer includes at least one sheet of compressed particles of exfoliated graphite and each artificial graphite layer includes at least one sheet selected from either pyrolytic graphite or sheets of graphitized polyimide film. Commercial artificial and natural graphite composites can include, but are not limited to, eGRAF® NeoNxGen™ thermal management solutions (NeoGraf Solutions, LLC Lakewood, Ohio).

The graphite sheet of the present disclosure can have a thickness of from 5 μm to 600 μm, or from 15 μm to 600 μm, or from 15 μm to 500 μm, or from 100 μm to 500 μm, or from 5 μm to 300 μm, or from 20 μm to 300 μm, or from 10 μm to 250 μm, or from 20 μm to 200 μm, or from 50 μm to 200 μm, or from 25 μm to 150 μm, or from 30 μm to 100 μm.

For the graphite sheet, thermal conductivity of the sheet in the in-plane direction can be varied from 250 to 2,500 W/m·K, or from 500 to 2,500 W/m·K, or from 600 to 2,500 W/m·K, or from 700 to 2,500 W/m·K. The thermal conductivity of the graphite sheet in the in-plane direction can be obtained by measuring the thermal diffusivity, specific heat, and density. These parameters can be measured using a thermal diffusivity measurement system [e.g., LaserPIT (Angstrom method), Bethel Thermowave Analyzer TA35 (Angstrom method), and laser flash or xenon flash thermal-diffusivity measuring device], a differential scanning calorimetry (DSC), and an Archimedes or Helium pycnometry method, respectively, and subsequently multiplying the measured values. The in-plane thermal diffusivity of the graphite sheet can vary from 125 to 1,250 mm²/s, or from 250 to 1,250 mm²/s, or from 300 to 1,250 mm²/s, or from 350 to 1,250 mm²/s.

In the present disclosure, the vias, slits, or louvers can be formed or perforated in the graphite sheet by any of Computer Numerical Control (CNC) drilling, Electro Discharge Machining (EDM), Electro Discharge Grinding (EDG), die cutting, laser drilling, plasma, or other methods known in the art at a desired shape, size and spacing to produce optimized results. The vias or slits can be placed at the edge of the graphite sheet. In some embodiments, vias can be drilled on the graphite sheet by using methods known in the art including CNC drilling, EDM, EDG, die cutting, laser drilling, and plasma. Slits can be fabricated in the graphite sheet. Alternatively, the vias, slits, or louvers can be formed or perforated first in the aromatic polyimide film using the techniques for the graphite sheet described above before graphitization.

In some embodiments, the vias, slits or louvers can occupy from 0.1 to 90, or from 1 to 90, or from 10 to 90, or from 0.1 to 50, from 0.1 to 1, or from 1 to 10, volume percent of the graphite sheet based the total volume of the graphite sheet.

In some embodiments, the spacing of the vias, slits or louvers may range from 0.5 to 250 mm, or from 1 to 200 mm, or from 1.5 to 100 mm to reach optimal desired results. In some embodiments, the graphite sheet can comprise notches derived from the vias, slits, or their combinations thereof.

In some embodiments, the vias can have shapes of circles, ovals, polygons, or combinations thereof. In one embodiment, the polygons can be selected from the group consisting of triangles, rectangles, squares, diamonds, trapezoids, pentagons, hexagons, heptagons, octagons, nonagons, decagons, dodecagons, and combinations thereof. The polygons can be regular, irregular, or a combination thereof. A polygon is regular when all angles are equal and all sides are equal.

In the graphite sheet containing vias, slits or their combinations, the arrangements or patterns of the vias, slits, or their combinations can be regular or irregular. The combinations and/or patterns will depend on the specific design requirements of applications. In some embodiments, the patterns of the vias can include, but are not limited to a square, hexagonal, and parallelogram lattice.

An open area of a single via or slit of the graphite sheet can range from 0.01 to 500 mm², or from 0.1 to 500 mm², or from 1 to 500 mm², or from 1 to 300 mm². The open area refers to the area of the single via or slit when seen in a direction of perpendicular to the graphite sheet. In one embodiment, the vias can have the circular shape. A diameter of the circle can range from 0.1 mm to 5 mm, or from 0.2 mm to 5 mm, or from 0.5 mm to 4 mm, or from 0.75 mm to 3.5 mm, or from 1 mm to 3 mm, or from 1.2 mm to 3 mm.

In some embodiments, at least one edge of the graphite sheet can comprise teeth and notches derived from the vias. The notches can be any shapes or cross-sections, including but not limited to rectangular, semi-circular, square, sinusoidal, sawtooth, and triangular. In one embodiment, the graphite sheet comprises the teeth and notches along at least one edge of the graphite sheet without any vias in the graphite sheet.

The substrate of the present disclosure can be a metal foil or a polymer film. The metal foil can be selected from the group consisting of copper, aluminum, tungsten, molybdenum, nickel, iron, stainless steel, silver, tin, gold and alloys of two or more of the above metals. In one embodiment, the substrate is a copper foil or a stainless steel foil. In some embodiments, the substrate comprises a multilayer metal foil. The multilayer metal foil can comprise at least two layers of metal foils. In one embodiment, the multilayer metal foil can comprise two, three or more layers of metal foil. The multilayer metal foil can be made from the same or different metals for the layers. The thickness of the substrates may be selected as desired for a particular purpose or intended application. In one embodiment, the substrates may each have a thickness of from 2 μm to 2 mm, or from 5 μm to 1.5 mm, or from 10 μm to 1 mm, or from 10 μm to 750 μm, or from 20 μm to 500 μm, or from 50 μm to 300 μm, or from 50 μm to 250 μm, or from 50 μm to 200 μm.

Examples of suitable polymers used for making the polymer film can include, but are not limited to, polyimide, polyamide-imide, polyamide, polyethersulfone, poly(ethylene terephthalate), poly(ethylene naphthalate), poly(ethylene), poly(propylene), poly(ethylene-co-vinylacetate), polyetherketone, cyclic olefin copolymer, polyesterimide, polycarbonate, polyethylmethacrylate, or their combinations.

The adhesive layer comprises an organic material selected from the group consisting of silicone, silicone-(meth)acrylate, silicone-epoxy, polyurethane-(meth)acrylate, poly(meth)acrylate, poly(alkyl)acrylate, polybutadiene, a block copolymer of styrene and butadiene, polystyrene, polysaccharide, ethylene vinyl acetate (EVA), polydimethylsiloxane (PDMS), polyurethane (PU), vinyl ether polymers, epoxy, phenolic resin, protein-derived adhesive, polymers containing acrylic acid or methacrylic acid, polymers containing poly(hydroxyethyl)acrylate, and combinations thereof. In some embodiments, the adhesive layer can comprise a pressure sensitive adhesive. Commercially available adhesives suitable for the present disclosure can include, but are not limited to, Temprion™ AT07000 Series Adhesive Thermal Tape (AT, DuPont de Nemours, Inc., Wilmington, Del.), and ARclad® 93319 (Adhesives Research®, Glen Rock, Pa.).

In some embodiments, the adhesive layer can be a thermally and/or electronically conductive adhesive layer. The thermally and/or electronically conductive adhesive layer can comprise an organic material and one or more thermally and/or electronically conductive filling materials. The organic materials are the same as those described previously. The thermally and/or electronically conductive adhesive layer can have good thermal and/or electronic conductivity and strong adhering property. The thermal and/or electronic conductive filling material can be selected from at least one of metal, metallic oxide, carbon material, nitride, carbide, and silicon material. The metal can be selected from at least one of silver, copper, aluminum, nickel, gold, and tin. The metallic oxide can be selected from at least one of aluminum oxide, magnesium oxide, zinc oxide, beryllium oxide, titanium oxide, antimony oxide, and tin oxide. The carbon material can be selected from at least one of carbon black, hard carbon, soft carbon, mesocarbon microbead, carbon nano tube, graphite, and graphene. The nitride can be selected from at least one of silicon nitride, aluminum nitride, boron nitride, and titanium nitride. The carbide can be selected from at least one of silicon carbide, and tungsten carbide. The silicon material can be selected from at least one of Si, and SiOₓ, 0<x≤2, 0<y≤2.

Commercially available electronically conductive adhesives suitable for the present disclosure can include, but are not limited to, ARclad® 8006 and ARclad® 9032-70 (Adhesives Research®, Glen Rock, Pa.).

The thickness of the adhesive layer can be varied from 1 to 200 μm, or from 1 to 100 μm, or from 1 to 50 μm, or from 5 to 50 μm, or from 5 to 40 μm, or from 5 to 30 μm, or from 10 to 30 μm.

The graphite sheet, the adhesive layer and the substrate of the flexible multifunctional laminate may have the same or different in-plane dimensions. In some embodiments, the adhesive layer may have a smaller dimension than the graphite sheet or the substrate. In some embodiments, the adhesive layer may have a bigger dimension across the adhesive layer than a dimension across the graphite sheet or the substrate such that the adhesive layer defines an overhang region at an edge of the adhesive layer that extends beyond a corresponding edge of the graphite sheet or the substrate. In some embodiments, the substrate may have a smaller dimension than the graphite sheet. In some embodiments, the substrate may have a bigger dimension across the substrate than a dimension across the graphite sheet such that the substrate defines an overhang region at an edge of the substrate that extends beyond a corresponding edge of the graphite sheet. In one embodiment, a length of the overhang region can range from 0.1 mm to 10 mm, or from 0.1 mm to 1 mm, or from 1 mm to 10 mm.

In some embodiments, the multifunctional flexible laminate comprising two or more graphite sheets will have vias, slits, louvers, or their combinations. The vias, slits or louvers on the different graphite sheets can be arranged for alignment or may be offset. In one embodiment, the vias, slits or louvers can align in all of the graphite sheets in a multifunctional flexible laminate. In another embodiment, the vias, slits or louvers are offset in all of the graphite sheets in a multifunctional flexible sheet. In yet another embodiment, the vias, slits or louvers can align each other in some of the graphite sheets but are offset in other of the graphite sheets.

The multifunctional flexible laminate of the present disclosure can further comprise a secondary substrate on which the substrate of the multifunctional flexible laminate is disposed. Examples of the secondary substrates can include, but are not limited to, chip, circuit board, glass fiber reinforced polymer (GFRP) sheet, glass, flexible circuitry, fabrics, ceramics, building materials, composites, polymer sheets including, but not limited to, polyimide, polyethylene terephthalate, polyethylene naphthalate, acrylic, polycarbonate, nylon, polyethylene, and polypropylene.

A multifunctional flexible laminate may be made by providing different layers; and laminating them under pressure and at elevated temperatures as with a Carver press (Carver, Inc., Wabash Ind.) or Riston® laminator (DuPont de Nemours, Inc., Wilmington, Del.). In one embodiment, the different layers can comprise a substrate, at least one graphite sheet, and at least one adhesive layer. In another embodiment, the different layers can comprise at least one graphite sheets and at least one adhesive layers. The pressure in the lamination process can range from 1 atm to 10 atm, or from 3 atm to 100 atm, or from 10 atm to 1000 atm. The temperature of the lamination process can range from −10° C. to 300° C., or from 15° C. to 200° C., or from 20° C. to 150° C. The rate at which the materials can pass through the laminator nip can range from 0.01 to 1 m/s, or from 0.1 to 10 m/s, or from 1 to 100 m/s.

The multifunctional flexible laminate has improved thermal and mechanical properties. Thermal properties of the multifunctional flexible laminate can include, for example, thermal conductivity, thermal conductance, specific heat capacity, heat capacity, thermal diffusivity, or the like. Thermal conductivity is proportional to the intrinsic temperature difference across a distance in response to an applied heat flux through a material, with typical units of power per length-temperature, such as Watts per meter-Kelvin. Thermal conductance is the time rate of steady-state heat flow through a unit area of a material induced by a unit temperature difference between the body surfaces, with typical units of power per temperature, such as Watts per Kelvin. Specific heat capacity is intrinsic temperature rise in response to heat energy, with typical units of energy per mass-temperature, such as Joules per kilogram-Kelvin. Heat capacity includes mass of material, with typical units of energy per temperature, such as Joules per Kelvin. Thermal diffusivity is the ratio of thermal conductivity to the product of mass density and specific heat capacity and indicates how quickly a material would reach a temperature similar to its surrounding environment, with typical units of area per time, such as square meters per second.

The thermal properties of the laminates may be measured using the methods known to a person of ordinary skill in the art. For example, Angstrom or thermal wave technique is often used for measuring thermal diffusivity of solid materials. The thermal diffusivity of a material is normally directly measured by utilizing transient methods that uses the measured transient temperature response to a time varying heat source. The transient methods are classified into transitory and periodic temperature methods. In transitory methods the thermal diffusivity is estimated from the sample temperature response to a sudden change in input heat. A well-known example is the flash method such as laser flash analysis or Xenon lamp flash analysis. In the periodic temperature method, thermal diffusivity is estimated from the sample response to a periodic (time varying) heat input. Examples can include 3ω-method and the Angstrom method. Other methods for measuring thermal properties can include, but are not limited to, transient grating spectroscopy, beam deflection techniques, thermal imaging techniques, standard test methods for measuring thermal transmission properties of thermal interface materials according to ASTM D5470-12, and thermal cycling.

Mechanical properties of the multifunctional flexible laminate can include adhesion strength and bendability. The mechanical performance of the multifunctional flexible laminates may be evaluated using techniques such as peel tests, double cantilever beam test, 3-point and 4-point bend testing methods, mandrel bend testing, high and low strain rate shear testing, impact testing, tensile testing, and techniques for measuring flexural rigidity.

The present disclosure is directed to a protective device that can be used to dissipate heat and/or shield electromagnetic interference for protecting an electronic device. The protective device comprises the multifunctional flexible laminate that is described as above. The protective device can have a thermal conductivity ranging from 100 W/m·K to 2,500 W/m·K, or from 200 W/m·K to 1,000 W/m·K, or from 400 W/m·K to 800 W/m·K; a thermal diffusivity ranging from 50 to 1,250 mm²/s, or from 100 to 500 mm²/s, or from 200 to 400 mm²/s; and/or an electromagnetic interference shielding effectiveness ranging from 5 dB to 100 dB, or from 10 dB to 100 dB, or from 30 dB to 100 dB, or from 10 dB to 95 dB, or from 20 to 90 dB.

The present disclosure is also directed to an electronic device comprising a heat source and the protective device described above. The adhesive layer of the multifunctional flexible laminate of the protective device is adhered to a heat source or a heat sink of the electronic device. A shape of the multifunctional flexible laminate in the electronic device is not particularly restricted as long as the adhesive layer of the laminate is in an indirect or direct contact with the heating source or heat sink of the electronic device. However, in view of the heat dissipation and/or electromagnetic shielding performance, a contact area with a surface of the heat source or heat sink can be as wide as possible. In some embodiments, the multifunctional flexible laminate can have a shape responding to a shape of the surface of the heating source in the electronic device.

The size of the multifunctional flexible laminate in the electronic device is not particularly restricted, either. However, if the heat-dissipation performance of the laminate is considered, as an area of the surface on a side in contact with the heating source or heat sink, the laminate can have the area identical with, smaller than, or larger than a surface area of the heating source or heat sink.

The present disclosure is also directed to an electromagnetic interference (EMI) shielding device comprising the multifunctional flexible laminate as described previously. The multifunctional flexible laminate can provide high EMI shielding effectiveness (SE). The SE is a sum of absorption, reflection, and multiple reflections in the shield materials.

In one aspect, an electromagnetic interference shielding device including an electrical circuit in need of electromagnetic interference shielding is provided. In one embodiment, the device includes a body at least partially surrounding the electrical circuit. The body comprises the multifunctional flexible laminates of the present disclosure. The electromagnetic interference shielding capabilities may be measured using methods like microwave transmission techniques.

In some embodiments, the multifunctional flexible laminate can provide an electromagnetic interference shielding effectiveness ranging from 5 dB to 100 dB, or from 10 dB to 100 dB, or from 30 dB to 100 dB, or from 10 dB to 95 dB, or from 20 to 90 dB. In one embodiment, the multifunctional flexible laminate provides an electromagnetic interference shielding effectiveness ranging from 10 dB to 100 dB. In another embodiments, the multifunctional flexible laminate provides an electromagnetic interference shielding effectiveness greater than 100 dB. In yet another embodiment, the multifunctional flexible laminate provides an electromagnetic interference shielding effectiveness of at least 5 dB.

The EMI shielding device of the present disclosure may be used in essentially any application in which EMI shielding is desired, and are particularly useful in applications where lightweight and/or thin construction is important or desirable.

In one aspect, a method is provided for shielding an electrical circuit from electromagnetic interference. In one embodiment, this method includes positioning the multifunctional flexible laminate of the present disclosure between the electrical circuit and an electromagnetic energy transmission source (e.g., VHF/UHF, microwave or radio wave signal generator). Non-limiting examples of devices which may include an electrical circuit in need of EMI shielding include computers for home use, computers for data centers, notebook computers, tablet computers, laptop computers, smartwatches, mobile and landline telephones, televisions, radios, personal digital assistants, digital music players, medical instruments, automotive vehicles, aircraft, and satellites.

### Examples

### Materials

Artificial Graphite Sheet (AGS): TG-818 synthetic graphite product (Spreadershield™ Heat Spreaders) with a thickness of 50±10 μm, an in-plane thermal conductivity of 1400 W/m·K, and a through-plane thermal conductivity of 3.4 W/m·K.

Artificial/Natural Graphite Composite Sheet (AGS/NGS): eGRAF® NeoNxGen™ Thermal Management Solutions of N-80 with a thickness of 80±10 μm, an in-plane thermal conductivity of 900 W/m·K, and a through-plane thermal conductivity of 4.5 W/m·K; N-100 with a thickness of 100±10 μm, an in-plane thermal conductivity of 1100 W/m·K, and a through-plane thermal conductivity of 4.5 W/m·K; N-150 with a thickness of 150±10 μm, an in-plane thermal conductivity of 1100 W/m·K, and a through-plane thermal conductivity of 4.5 W/m·K; and N-200 with a thickness of 200±10 μm, an in-plane thermal conductivity of 1100 W/m·K, and a through-plane thermal conductivity of 4.5 W/m·K.

The AGS and AGS/NGS listed above were commercially available from NeoGraf™ Solutions, Lakewood, Ohio and used to drill holes as described below.

Adhesives: DuPont™ Temprion™ AT07000 Adhesive Thermal Tape (AT, commercially available from DuPont de Nemours, Inc., Wilmington, Del.) with a thickness of 2 mil (50.8 μm), a thermal conductivity of 0.7 W/m·K, and a 90° peel strength of 1.6 lb/in (against aluminum after a 1 hr. dwell time). The adhesive was colored white and sandwiched between two clear release liners.

Adhesives Research® ARclad® 93319 was a low surface energy transfer film (AR, commercially available from Adhesives Research Inc., Glen Rock, Pa.) with a thickness of 2.2 mil (55 μm) and a 180° peel strength of 5.2 lb/in (against stainless steel after a 5 min dwell time). The low surface energy tape was clear and was lined on one side by a white release liner.

Adhesives Research® ARclad® 9032-70 was a highly electrically conductive pressure sensitive adhesive transfer film made (eAR, commercially available from Adhesives Research Inc., Glen Rock, Pa.) with a thickness of 1 mil (25.4 μm), a volume electrical resistance of ≤10 mΩ, and a 180° peel strength of ˜30 oz/in (against stainless deal after a 1 hr dwell time). The electrically conductive pressure-sensitive adhesive was colored black and was lined on one side by a clear polyester and the other side by a white polyester.

3M™ 8211 Optically Clear Adhesive was an optically clear acrylic free-film (OCA, commercially available from 3M™, Saint Paul, Minn.) with a thickness of 1 mil (25.4 μm) and a 180° peel strength of 54 oz/in (against glass deal after a 20 min dwell time). The optically clear adhesive film was sandwiched between two clear polyester release liners.

Copper Foils (Cu Foil): McMaster-Carr® 110 Copper (Cu) Shim Stock (McMaster-Carr Company, Elmhurst, Ill.) had a thickness of 4 mil (101.6 μm) as a Cu foil(4) or 1 mil (25.4 μm) as a Cu foil(1).

Polyimide Film: DuPont™ Kapton® HN was a general-purpose polyimide film (PI, commercially available from DuPont de Nemours, Inc., Wilmington, Del.) with a thickness of 1 mil (25.4 μm).

### Graphite Sheets Having Holes (hAGS and hAGS/NGS)

A DATRON neo Computer Numerical Control (CNC) milling machine (DATRON Dynamics Inc., Milford, N.J.), equipped with a 1.35 mm drill bit, was programmed to drill 1.35 mm diameter holes through the AGS and AGS/NGS in a hexagonal close-packed pattern with center-to-center distances of 5 mm (hAGS and hAGS/NGS). The aforementioned hole diameter and pattern were drilled into the AGS with thickness of 50 μm [hAGS(50)]; and the AGS/NGS with thicknesses of 80 μm [hAGS/NGS(80)], 150 μm [hAGS/NGS(150)] and 200 μm [hAGS/NGS(200)]. By total volume, the resulting CNC milled AGS and AGS/NGS contained 6.61% holes. The hAGS and hAGS/NGS prepared were used to make laminates in the following Examples 1 to 8.

A ProtoLaser U3 CNC milling machine (LPKF Laser & Electronics, Garbsen, Germany) equipped with a third hormonic Nd:YAG laser that was q-switched at 355 nm with a spot diameter of 20 μm, was programmed to mill rectangular holes through AGS/NGS. The rectangular holes were milled to create perimeter features around 8 mm×160 mm parts tiled throughout the area of the AGS/NGS. Centered along the 8 mm edge was a 1.35×4 mm hole (the 4 mm dimension was parallel to the part edge). Along the 160 mm edge were five 1.35×29.6 mm holes (the 29.6 mm dimension was parallel to the part edge) spaced by 2 mm. The aforementioned pattern was drilled into AGS/NGS with a thickness of 100 μm [hAGS/NGS(100)]. By volume of individual parts, the resulting laser milled hAGS/NGS(100) contained 16.03% holes. The hAGS/NGS(100) prepared was used to make laminates in Examples 9 to 12.

### Laminates

### Example 1

A Cu foil(4)-hAGS(50)-AT laminate was made by removing the first release liner from the AT layer to expose adhesive and applying the hAGS(50) to the exposed adhesive to form a hAGS(50)-AT substructure. The hAGS(50) side of the hAGS(50)-AT substructure was then applied to the Cu foil(4) so that the exposed adhesive contacted the Cu foil(4) through the holes and around the edges of the hAGS(50) to form a composite. With the hAGS(50) dimensions smaller than the Cu foil(4) and AT dimensions, the AT overhung the hAGS(50) and created a 5 mm border with the Cu foil(4). The composite was then laminated through an HRL-24 DuPont™ Riston® laminator (DuPont de Nemours, Inc., Wilmington, Del.) at a roll speed of 0.1 m/min and with upper and lower roll temperatures of 100° C. After the lamination, the excess AT material was trimmed at the edges. The final Cu foil(4)-hAGS(50)-AT laminate included the second release liner on the AT.

### Example 2

A Cu foil(4)-AT-hAGS(50)-AT laminate was constructed by removing the first release liner from the first AT layer to expose adhesive and applying the exposed adhesive to one side of the Cu foil(4) to form a Cu foil(4)-AT substructure. The Cu foil(4)-AT substructure was laminated through an HRL-24 DuPont™ Riston® laminator at a roll speed of 0.1 m/min and with upper and lower roll temperatures of 100° C. After the lamination, the excess AT was trimmed at the edges and the second release liner of the first AT layer was removed to expose AT adhesive of the Cu foil(4)-AT substructure. Next, the hAGS(50) was applied to the exposed AT adhesive of the Cu foil(4)-AT substructure to form a Cu foil(4)-AT-hAGS(50) substructure. The first release liner from the second AT layer was then removed and applied to the hAGS(50) side of the Cu foil(4)-AT-hAGS(50) substructure to form a composite. The two AT layers consequently made contact through the holes and around the edges of the hAGS(50). With the hAGS(50) dimensions smaller than the overall dimensions of the Cu foil(4) and AT layers, the AT layers overhung the hAGS(50) and created a 5 mm border. The composite was then laminated through an HRL-24 DuPont™ Riston® laminator at a roll speed of 0.1 m/min and with upper and lower roll temperatures of 100° C. After the lamination, the excess AT material from the second adhesive layer was trimmed at the edges. The final Cu foil(4)-AT-hAGS(50)-AT laminate included the second release liner on the second AT layer.

### Example 3

An AT-hAGS(50)-AT laminate was prepared by removing the first release liner from the first AT layer to expose adhesive and applying an hAGS(50) to the exposed adhesive to form an AT-hAGS(50) substructure. Next, the first release liner from the second AT layer was removed and applied to the hAGS(50) side of the AT-hAGS(50) substructure to form a composite. The two AT layers consequently made contact through the holes and around the edges of the hAGS(50). The composite was then laminated through an HRL-24 DuPont™ Riston® laminator at a roll speed of 0.1 m/min and with upper and lower roll temperatures of 100° C. After the lamination, the excess AT material was trimmed. With the hAGS(50) dimensions smaller than the overall dimensions of the AT layers, the AT layers overhung the hAGS(50) by 5 mm. The final AT-hAGS(50)-AT laminate included the second release liners on both AT layers.

### Example 4

An AT-hAGS/NGS(80)-AT laminate was constructed by removing the first release liner from the first AT layer to expose adhesive and applying the hAGS/NGS(80) to the exposed adhesive to form an AT-hAGS/NGS(80) substructure. Next, the first release liner from the second AT layer was removed and applied to the hAGS/NGS(80) side of the AT-hAGS/NGS(80) substructure to form a composite. The two AT layers consequently made contact through the holes and around the edges of the hAGS/NGS(80). The composite was then laminated through an HRL-24 DuPont™ Riston® laminator at a roll speed of 0.1 m/min and with upper and lower roll temperatures of 100° C. After the lamination, the excess AT material was trimmed. With the hAGS/NGS(80) dimensions smaller than the overall dimensions of the AT layers, the AT layers overhung the hAGS/NGS(80) by 5 mm. The final AT-hAGS/NGS(80)-AT laminate included the second release liners on both AT layers.

### Example 5

An AT-hAGS/NGS(150)-AT laminate was made by removing the first release liner from the first AT layer to expose adhesive and applying the hAGS/NGS(150) to the exposed adhesive to form an AT-hAGS/NGS(150) substructure. Next, the first release liner from the second AT layer was removed and applied to the hAGS/NGS(150) side of the AT-hAGS/NGS(150) substructure to form a composite. The two AT layers consequently made contact through the holes and around the edges of the hAGS/NGS(150). The composite was then laminated through an HRL-24 DuPont™ Riston® laminator at a roll speed of 0.1 m/min and with upper and lower roll temperatures of 100° C. After the lamination, the excess AT material was trimmed. With the hAGS/NGS(150) dimensions smaller than the overall dimensions of the two AT layers, the AT layers overhung the hAGS/NGS(150) by 5 mm. The final AT-hAGS/NGS(150)-AT laminate included the second release liners on both AT layers.

### Example 6

An AT-hAGS/NGS(200)-AT laminate was prepared by removing the first release liner from the first AT layer to expose adhesive and applying the hAGS/NGS(200) to the exposed adhesive to form an AT-hAGS/NGS(200) substructure. Next, the first release liner from the second AT layer was removed and applied to the hAGS/NGS(200) side of the AT-hAGS/NGS(200) substructure to form a composite. The two AT layers consequently made contact through the holes and around the edges of the hAGS/NGS(200). The composite was then laminated through an HRL-24 DuPont™ Riston® laminator at a roll speed of 0.1 m/min and with upper and lower roll temperatures of 100° C. After the lamination, the excess AT material was trimmed. With the hAGS/NGS(200) dimensions smaller than the overall dimensions of the two AT layers, the AT layers overhung the hAGS/NGS(200) by 5 mm. The final AT-hAGS/NGS(200)-AT laminate included the second release liners on both AT layers.

### Example 7

A Cu foil(4)-hAGS(50)-AR laminate was constructed by unrolling, cutting a section of AR from its self-wound spool and adhering it to the hAGS(50) to form a hAGS(50)-AR substructure. The hAGS(50)-AR substructure was then applied to the Cu foil(4) so that the exposed adhesive contacted the Cu foil(4) through the holes and around the edges of the hAGS(50) to form a composite. With the hAGS(50) dimensions smaller than the Cu foil(4) dimensions, the AR overhung the hAGS(50) and created a 5 mm border with the Cu foil(4). The composite was then laminated through an HRL-24 DuPont™ Riston® laminator at a roll speed of 0.1 m/min and with upper and lower roll temperatures of 100° C. After the lamination, the excess AR material was trimmed at the edges. The final Cu foil(4)-hAGS(50)-AR laminate included the release liner on the AR layer.

### Example 8

A Cu foil(4)-AR-hAGS(50)-AR laminate was made by unrolling, cutting a section of AR from its self-wound spool and applying it to the Cu foil(4) to form a Cu foil(4)-AR substructure. The Cu foil(4)-AR substructure was laminated through an HRL-24 DuPont™ Riston® laminator at a roll speed of 0.1 m/min and with upper and lower roll temperatures of 100° C. After the lamination, the excess AR was trimmed at the edges and the release liner was removed to expose the AR adhesive of the Cu foil(4)-AR substructure. Next, the hAGS(50) was applied to the exposed AR adhesive side of the Cu foil(4)-AR substructure to form a Cu foil(4)-AR-hAGS(50) substructure. A second section of AR was unrolled and cut from its self-wound spool, The exposed adhesive was applied to the hAGS(50) side of the Cu foil(4)-AR-hAGS(50) substructure to form a composite. The two AR layers consequently made contact through the holes and around the edges of the hAGS(50). With the hAGS(50) dimensions smaller than the overall dimensions of the two AR layers, the AR layers overhung the hAGS(50) and created a 5 mm border. The composite was then laminated through an HRL-24 DuPont™ Riston® laminator at a roll speed of 0.1 m/min and with upper and lower roll temperatures of 100° C. After the lamination, the excess AR material from the second AR layer was trimmed at the edges. The final Cu foil(4)-AR-hAGS(50)-AR laminate included the release liner on the second AR layer.

### Example 9

A Cu foil(1)-eAR-hAGS/NGS(100)-eAR-Cu foil(1) was constructed by removing the first release liner from the first eAR layer to expose adhesive and applying the exposed adhesive to one side of the first Cu foil(1) to form a first Cu foil(1)-eAR substructure. The first release liner from the second eAR layer was removed to expose adhesive and the exposed adhesive was applied to one side of the second Cu foil(1) to form a second Cu foil(1)-eAR substructure. The first and second Cu foil(1)-eAR substructures were laminated through an HRL-24 DuPont™ Riston® laminator at a roll speed of 0.1 m/min, respectively. Next, the second release liner of the first eAR layer was removed to expose eAR adhesive of the first Cu foil(1)-eAR substructure. The exposed eAR adhesive of the first Cu foil(1)-eAR substructure was then applied to the hAGS/NGS(100) and laminated through an HRL-24 DuPont™ Riston® laminator at a roll speed of 0.1 m/min to form a Cu foil(1)-eAR-hAGS/NGS(100) substructure. Then, the second release liner of the second eAR layer was removed to expose eAR adhesive of the second Cu foil(1)-eAR substructure and applied to the hAGS/NGS(100) side of the Cu foil(1)-eAR-hAGS/NGS(100) substructure to form a composite. The two eAR layers consequently made contact through the rectangular holes of the hAGS/NGS(100). The final composite was then laminated through an HRL-24 DuPont™ Riston® laminator at a roll speed of 0.1 m/min and with upper and lower roll temperatures of 100° C.

### Example 10

A Cu foil(1)-OCA-hAGS/NGS(100)-OCA-Cu foil(1) was constructed by removing the first release liner from the first OCA layer to expose adhesive and applying the exposed adhesive to one side of the first Cu foil(1) to form a first Cu foil(1)-OCA substructure. The first release liner from the second OCA layer was removed to expose adhesive and the exposed adhesive was applied to one side of the second Cu foil(1) to form a second Cu foil(1)-OCA substructure. The first and second Cu foil(1)-OCA substructures were laminated through an HRL-24 DuPont™ Riston® laminator at a roll speed of 0.1 m/min, respectively. Next, the second release liner of the first OCA layer was removed to expose OCA adhesive of the first Cu foil(1)-OCA substructure. The exposed OCA adhesive of the first Cu foil(1)-OCA substructure was then applied to the hAGS/NGS(100) and laminated through an HRL-24 DuPont™ Riston® laminator at a roll speed of 0.1 m/min to form a Cu foil(1)-OCA-hAGS/NGS(100) substructure. Next, the second release liner of the second OCA layer was removed to expose OCA adhesive of the second Cu foil(1)-OCA substructure and applied to the hAGS/NGS(100) side of the Cu foil(1)-OCA-hAGS/NGS(100) substructure to form a composite. The two OCA layers consequently made contact through the rectangular holes of the hAGS/NGS(100). The final composite was then laminated through an HRL-24 DuPont™ Riston® laminator at a roll speed of 0.1 m/min and with upper and lower roll temperatures of 100° C.

### Example 11

A PI-OCA-hAGS/NGS(100)-OCA-PI was constructed by removing the first release liner from the first OCA layer to expose adhesive and applying the exposed adhesive to one side of the first PI to form a first PI-OCA substructure. The first release liner from the second OCA layer was removed to expose adhesive and the exposed adhesive was applied to one side of the second PI to form a second PI-OCA substructure. The first and second PI-OCA substructures were laminated through an HRL-24 DuPont™ Riston® laminator at a roll speed of 0.1 m/min, respectively. Next, the second release liner of the first OCA layer was removed to expose OCA adhesive of the first PI-OCA substructure. The exposed OCA adhesive of the first PI-OCA substructure was then applied to the hAGS/NGS(100) and laminated through an HRL-24 DuPont™ Riston® laminator at a roll speed of 0.1 m/min to form a PI-OCA-hAGS/NGS(100) substructure. Then, the second release liner of the second OCA layer was removed to expose OCA adhesive of the second PI-OCA substructure and applied to the hAGS/NGS(100) side of the PI-OCA-hAGS/NGS(100) substructure to form a composite. The two OCA layers consequently made contact through the rectangular holes of the hAGS/NGS(100). The final composite was then laminated through an HRL-24 DuPont™ Riston® laminator at a roll speed of 0.1 m/min and with upper and lower roll temperatures of 100° C.

### Example 12

A hAGS/NGS(100)-OCA-Cu foil(1)-OCA-hAGS/NGS(100) laminate was constructed by removing the first release liner from the first OCA layer to expose adhesive and applying the exposed adhesive to one side of the first Cu foil(1) to form a Cu foil(1)-OCA substructure. The Cu foil(1)-OCA substructure was laminated through an HRL-24 DuPont™ Riston® laminator at a roll speed of 0.1 m/min. The first release liner from the second OCA layer was removed to expose adhesive and the exposed adhesive was applied to the Cu-foil(1) side of the Cu-foil(1)-OCA substructure to create an OCA-Cu foil(1)-OCA substructure. The OCA-Cu foil(1)-OCA substructure was laminated through an HRL-24 DuPont™ Riston® laminator at a roll speed of 0.1 m/min. Next, the second release liners of the first and second OCA layers of the OCA-Cu foil(1)-OCA substructure were removed to expose the OCA adhesive layers onto which two hAGS/NGS(100) sheets were applied to form a final composite. The final composite was then laminated through an HRL-24 DuPont™ Riston® laminator at a roll speed of 0.1 m/min and with upper and lower roll temperatures of 100° C.

### Thermal Diffusivity

The in-plane thermal diffusivities of the individual laminate layers were measured with a LaserPIT Thermal Diffusivity Measurement System (ULVAC-RIKO, Inc. Yokohama, Japan). The results are listed in Table 1.

TABLE 1
In-Plane Thermal Diffusivities of Laminate Components

| | | | | Measured In-Plane |
|---|---|---|---|---|
| | | | Thickness | Thermal Diffusivity |
| Material Name | Supplier | Abbreviation | (μm) | (mm²/s) |
| TG-818 Artificial Graphite Sheet | NeoGraf ™ Solutions | AGS(50) | 50 | 874 ± 21 |
| N-80 eGRAF ® NeoNxGen ™ | NeoGraf ™ Solutions | AGS/NGS(80) | 80 | 523 ± 17 |
| N-100 eGRAF ® NeoNxGen ™ | NeoGraf ™ Solutions | AGS/NGS(100) | 100 | 620 ± 48 |
| N-150 eGRAF ® NeoNxGen ™ | NeoGraf ™ Solutions | AGS/NGS(150) | 150 | 679 ± 59 |
| N-200 eGRAF ® NeoNxGen ™ | NeoGraf ™ Solutions | AGS(200) | 200 | 1061 ± 66 |
| Temprion ™ AT Adhesive Thermal Tape | DuPont de Nemours, Inc. | AT | 50.8 | 0.489 ± 0.088 |
| ARclad ® 93319 Developmental Tape | Adhesives Research ® | AR | 55 | 0.418 ± 0.149 |
| ARclad ® 9032-70 Electrically Conductive | Adhesives Research ® | eAR | 25.4 | 0.239 ± 0.006 |
| Pressure Sensitive Adhesive | | | | |
| 8211 Optically Clear Adhesive | 3M ™ | OCA | 25.4 | 0.149 ± 0.056 |
| Copper Foil | McMaster-Carr ® | Cu | 101.6 | 114 ± 1 |
| Kapton ® HN | DuPont de Nemours, Inc. | PI | 25.4 | 0.478 ± 0.010 |

Of the total volume of hAGS and hGAS/NGS used in the above Examples 1 to 8, 6.61% of the hAGS and the hAGS/NGS comprised of holes, thus the hAGS(50), hAGS/NGS(80), hAGS/NGS(150), and hAGS/NGS(200) was 93.39% as effective at spreading heat as the continuous sheet of AGS(50), AGS/NGS(80), AGS/NGS(150), and AGS/NGS(200), respectively. Therefore, the thermal diffusivities of hAGS(50), hAGS(80), hAGS(150), and hAGS(200) were approximated as 816±20 mm²/s, 488±16 mm²/s, 634±55 mm²/s, and 991±62 mm²/s, respectively. For Examples 9 to 12, 16.03% of the hAGS/NGS(100) comprised of holes, thus was 83.97% as effective at spreading heat as a continuous sheet of AGS/NGS(100). Therefore, the thermal diffusivity of hAGS/NGS(100) was approximated as 558±43 mm²/s.

The effective thermal diffusivity (α_{eff}) of the multifunctional flexible laminates can be calculated from Equation (1) shown below, based on the thermal diffusivities of the individual layers weighted by their respective thicknesses.

$${α}_{eff} = \frac{{\sum }_{i = 1}^{n} {t}_{i} {α}_{i}}{{\sum }_{i = i}^{n} {t}_{i}} \qquad Equation ( 1 )$$

where tᵢ is the thickness of each layer, aᵢ is the thermal diffusivity of each layer, and n is the total number of the layers. The calculated effective thermal diffusivities for the laminates prepared in Examples 1 to 12 are shown in Table 2. The calculated effective thermal diffusivities for the laminates are greater than the in-plane thermal diffusivity of the copper foil.

TABLE 2
Calculated Weighted Average of the Thermal Performance for Each Presented Example

| Example | Laminate | Calculated Effective Thermal Diffusivity (mm²/s) |
|---|---|---|
| Example 1 | Cu foil(4)-hAGS(50)-AT | 258 |
| Example 2 | Cu foil(4)-AT-hAGS(50)-AT | 206 |
| Example 3 | AT-hAGS(50)-AT | 270 |
| Example 4 | AT-hAGS/NGS(80)-AT | 215 |
| Example 5 | AT-hAGS/NGS(150)-AT | 378 |
| Example 6 | AT-hAGS/NGS(200)-AT | 657 |
| Example 7 | Cu foil(4)-hAGS(50)-AR | 253 |
| Example 8 | Cu foil(4)-AR-hAGS(50)-AR | 200 |
| Example 9 | Cu foil(1)-eAR-hAGS/NGS(100)-eAR-Cu foil(1) | 287 |
| Example 10 | Cu foil(1)-OCA-hAGS/NGS(100)-OCA-Cu foil(1) | 287 |
| Example 11 | PI-OCA-hAGS/NGS(100)-OCA-PI2 | 258 |
| Example 12 | hAGS/NGS(100)-OCA-Cu foil(1)-OCA-hAGS/NGS(100) | 458 |

### Electrical Resistance

The through-plane electrical resistances of Examples 9 and 10 were measured with a voltmeter. The Cu foil(1)-eAR-hAGS/NGS(100)-eAR-Cu foil(1) laminate in Example 9 had a through-plane electrical resistance of 0.4Ω and the Cu foil(1)-OCA-hAGS/NGS(100)-OCA-Cu foil(1) laminate in Example 10 as an infinite through-plane.

What is claimed is:

1. A multifunctional flexible laminate comprising a first and second adhesive layers, and a graphite sheet having a plurality of vias, slits or louvers sandwiched between the first and second adhesive layers.

2. A multifunctional flexible laminate comprising a substrate, a first graphite sheet disposed on the substrate, and a first adhesive layer disposed on the first graphite sheet, wherein the first graphite sheet has a plurality of vias, slits or louvers.

3. A multifunctional flexible laminate comprising a first graphite sheet, a first adhesive layer disposed on the first graphite sheet, a substrate disposed on the first adhesive layer, a second adhesive layer disposed on the substrate, and the second graphite sheet disposed on the second adhesive layer, wherein the first and second graphite sheets comprise a plurality of vias, slits or louvers.

4. The multifunctional flexible laminate of claim 1, wherein the vias, slits or louvers in the graphite sheet has a volume ranging from 0.1% to 90% based on the total volume of the graphite sheet.

5. The multifunctional flexible laminate of claim 1, wherein the spacing of the vias, slits or louvers ranges from 0.5 mm to 250 mm.

6. The multifunctional flexible laminate of claim 1, wherein the vias have shapes selected from the group consisting of circles, ovals, polygons, and combinations thereof.

7. The multifunctional flexible laminate of claim 1, wherein an open area of a single via or slit is varied from 0.01 to 500 mm².

8. The multifunctional flexible laminate of claims 1, wherein the graphite sheet is selected from the group consisting of an artificial graphite sheet, a natural graphite sheet, a composite sheet of artificial and natural graphite, and combinations thereof.

9. The multifunctional flexible laminate of claim 1, wherein the graphite sheet has a thickness of 5 to 600 μm.

10. The multifunctional flexible laminate of claim 1, wherein the substrate is a metal foil or a polymer film.

11. The multifunctional flexible laminate of claim 10, wherein the metal foil is selected from the group consisting of copper, aluminum, tungsten, molybdenum, nickel, iron, stainless steel, silver, tin, gold and alloys of two or more thereof.

12. The multifunctional flexible laminate of claim 11, the substrate comprises a multilayer metal foil.

13. The multifunctional flexible laminate of claim 12, wherein the multilayer metal foil comprises at least two layers of the metal foil.

14. The multifunctional flexible laminate of claim 1, wherein the substrate has a thickness ranging from 2 μm to 2 mm.

15. The multifunctional flexible laminate of claim 1, wherein the adhesive layer has a thickness ranging from 1 to 200 μm.

16. The multifunctional flexible laminate of claim 2, wherein the substrate, the graphite sheet and the adhesive layer have the same or different dimensions.

17. The multifunctional flexible laminate of claim 16, wherein the adhesive layer has a bigger dimension across the adhesive layer than a dimension across the graphite sheet such that the adhesive layer defines an overhang region at an edge of the adhesive layer that extends beyond a corresponding edge of the graphite sheet.

18. A protective device for dissipating heat or shielding electromagnetic interference for protecting an electronic device, comprising the multifunctional flexible laminate of claim 1.

19. An electronic device comprising a heat source and the protective device of claim 18, wherein the adhesive layer of the multifunctional flexible laminate is adhered to the heat source.

20. An electromagnetic interference shielded device, comprising the multifunctional flexible laminate of claim 1.
